(19) United States
(12) Patent Application Publication
(10) Pub. No.: US 2008/0037196 A1
(43) Pub. Date: Feb. 14, 2008

(54) Electrostatic chuck

(75) Inventors: Hiroshi Yonekura, Nagano (JP); Koki Tamagawa, Nagano (JP); Takeshi Kobayashi, Nagano (JP); Hitoshi Kaneko, Nagano (JP)

Correspondence Address: DRINKER BIDDLE & REATH (DC), 1500 K STREET, N.W., SUITE 1100, WASHINGTON, DC, 20005-1209, US

(73) Assignee: SHINKO ELECTRIC INDUSTRIES CO., LTD.

(21) Appl. No.: 11/882,908

(22) Filed: Aug. 7, 2007

(30) Foreign Application Priority Data
Aug. 8, 2006 (JP) P.2006-215631

(51) Int. Cl. H01L 21/683; B23B 5/22

(52) U.S. Cl. 361/234; 279/128

(57) ABSTRACT

An electrostatic chuck 15 for chucking and supporting a work 20 made of an electrical insulating material includes a chuck body having a positive electrode 12a and a negative electrode 12b formed therein to which positive and negative voltages are applied. An area ratio of the positive electrode 12a and the negative electrode 12b to a chucking surface of the chuck body is in the range of 60% to 90%.

### BACKGROUND OF THE INVENTION

The present invention relates to an electrostatic chuck, and more particularly to, an electrostatic chuck which chucks and supports a work made of an electrical insulating material such as a glass substrate used for a LCD panel.

In apparatuses for processing a semiconductor wafer and the like, an electrostatic chuck has been widely used as a delivery mechanism for chucking and supporting a work, and recently used to deliver an insulating material such as a liquid crystal panel. The mechanisms which generates a chucking force chucking and supporting the work by the electrostatic chuck is known to use (1) a Coulomb force acting between the work and the electrostatic chuck, (2) a Johnson Rahbeck force occurring at a contact interface between the work and the electrostatic chuck, and (3) a gradient force resulting from a non-uniform electric field generated between the work and the electrostatic chuck by the electrostatic chuck.

FIGS. 10A to 10C schematically show that a Coulomb force (FIG. 10A), a Johnson Rahbeck force (FIG. 10B), and a gradient force (FIG. 10C) act. The Coulomb force becomes dominant when the resistance of a dielectric layer constituting a chuck body 10 is high (about 10¹³ Ω·cm or more of volume resistivity), and the Johnson Rahbeck force becomes dominant when the chuck body 10 has a predetermined electric conductivity (about 10⁸ to 10¹² Ω·cm. The Coulomb force serves as a long-distance force acting between an electrode 12 of the chuck body 10 and a work 20, and the Johnson Rahbeck force results from a chucking force produced by a charge that is generated at a contact interface between the chuck body 10 and the work 20. Accordingly, the Johnson Rahbeck force acts stronger than the Coulomb force does when a conductor such as a semiconductor wafer is chucked (for example, see Patent Document 1).

A method of chucking a work using the gradient force has been suggested as a method of chucking a chucking object made of an electrical insulating material such as a glass substrate (for example, see Patent Documents 2 and 3). The gradient force serves to chuck and support the work by generating a non-uniform electric field on the surface of an electrostatic chuck. A pair of positive and negative electrodes is formed in a fine pattern of which the width and the interval are several mm or less and the electrode 12 is formed in the vicinity of the surface layer of a dielectric layer, so that the gradient force acts on the work.

[Patent Document 1]

Unexamined Japanese Patent Application Publication No. 2005-166820

[Patent Document 2]

Unexamined Japanese Patent Application Publication No. 2005-223185

[Patent Document 3]

Unexamined Japanese Patent Application Publication No. 2006-49852

A method of chucking and supporting a work by the use of a gradient force is used to chuck a work made of an electrical insulating material such as a glass substrate. However, the chucking operation resulting from the gradient force is not relatively large. Therefore, a small work can be chucked and supported by the operation resulting from the gradient force. However, a sufficient chucking force may not be obtained when a large-sized, heavy glass substrate having a side of 1 m such as a LCD panel is delivered.

Since the chucking force resulting from the gradient force can be increased by allowing a high voltage to be applied to electrodes, it is possible to chuck a work by applying a high voltage to the electrodes. However, when a work in which a circuit is formed on the surface of a substrate such as a LCD panel is handled and when a high voltage is applied to the electrodes, insulation breakdown may take place in the circuit or the work may be damaged by arc discharge.

On the other hand, when a voltage to be applied is lowered, the gradient force is reduced and therefore the work may move out of the original position thereof at the time of delivery. Accordingly, a delivery error may occur, or a high voltage may be generated in the circuit formed on the surface of the glass substrate and the circuit may be damaged.

When the work such as a large-sized LCD panel is delivered at high speed in the air, the work is easily charged by the contact with the air. Since there are many cases where the charging of the glass substrate which is an insulating material is generated from the inside thereof, it is not effective to use discharging means, such as an ionizer, which radiates ions from outside for neutralization. Accordingly, when the work in a charged state is delivered by an electrostatic chuck, a chucking force caused by the electrostatic chuck is removed. The work may move out of the original position thereof and therefore the work delivery error may occur.

The invention is contrived to solve the problems, and an object of the invention is to provide an electrostatic chuck which reliably chucks and supports even a large-sized work made of an electrical insulating material such as a LCD panel, and is adequately used for a work delivery operation and the like.

### SUMMARY OF THE INVENTION

It has been known that a chucking operation resulting from a gradient force can be used to chuck a work made of an electrical insulating material such as a glass substrate by the use of an electrostatic chuck. However, a chucking force resulting from a Coulomb force also acts on the work made of an electrical insulating material such as a glass substrate. The inventor has found that the chucking operation resulting from the Coulomb force effectively serves to chuck a work made of an electrical insulating material, particularly a large-sized work, owing to a form of an electrode pattern. The invention is to provide an electrostatic chuck which can effectively chucks and supports a work made of an electrical insulating material by effectively generating the chucking operation resulting from the Coulomb force.

That is, in the invention, there is provided an electrostatic chuck for chucking and supporting a work made of an electrical insulating material, the electrostatic chuck including:

a chuck body, and

positive and negative electrodes which are formed in the chuck body, and positive and negative voltages are applied to, wherein

an area ratio of the positive and negative electrodes to a chucking surface of the chuck body is in the range of 60% to 90%.

It is particularly preferable that the area ratio of the electrodes to the chucking surface of the chuck body is in the range of 70% to 80%.

Further, when the area of the chucking surface is 0.6 m² or more, the chuck body can be effectively used for an apparatus for chucking a large-sized work having an area of 0.6 m² or more.

Further, when the chuck body is formed of a dielectric material having a volume resistivity of 10¹³ Ω·cm or more, it is possible to effectively chuck and support the work made of an electrical insulating material such as a glass substrate.

Further, it is preferable that the positive and negative electrodes are formed in a parallel pattern and disposed in a pectinate shape.

Further, when the positive and negative electrodes are provided in layers separated from each other in a thickness direction of the chuck body, the area ratio of the electrodes to the chucking surface of the chuck body can be easily set to be increased while problems, such as electrical discharge between the electrodes, are avoided.

In an electrostatic chuck according to the invention, the area ratio of positive and negative electrodes to the chucking surface of the chuck body is in the range of 60% to 90% so that a Coulomb force can be effectively generated for a work made of an electrical insulating material such as a glass substrate. Accordingly, it is possible to reliably chuck and support even a large-sized work.

### BRIEF DESCRIPTION OF THE DRAWINGS

FIG. 1A is schematic diagrams illustrating a planar arrangement, and FIG. 1B is a sectional arrangement of electrodes formed in an electrostatic chuck.

FIG. 2A is schematic diagrams illustrating a planar arrangement, and FIG. 2B is a sectional arrangement of electrodes formed in an electrostatic chuck.

FIG. 3 is schematic diagrams illustrating a planar arrangement of electrodes formed in an electrostatic chuck.

FIG. 4 is a graph illustrating a relation between a chucking force per unit area and the area ratio of electrodes for three works having chucking areas different from one another.

FIG. 5 is a graph illustrating a relation between a chucking force and the size of a glass substrate for the cases where the area ratio of the electrodes is changed.

FIGS. 6A and 6B are sectional views illustrating another example of forming the electrodes formed in the electrostatic chuck.

FIG. 7 is a sectional view illustrating a further example of forming the electrodes formed in the electrostatic chuck.

FIG. 8A is schematic diagrams illustrating a planar arrangement, and FIG. 8B is a sectional arrangement of the electrodes, describing a method of chucking and supporting a charged work.

FIG. 9 is schematic diagrams illustrating another method of chucking and supporting the charged work.

FIGS. 10A to 10C are schematic diagrams illustrating chucking and supporting operations for a work, resulting from a Coulomb force (FIG. 10A), a Johnson Rahbeck force (FIG. 10B), and a gradient force (FIG. 10C).

### DETAILED DESCRIPTION OF THE PREFERRED EMBODIMENTS

Hereinafter, preferred embodiments of the invention will be concretely described with reference to the accompanying drawings.

(Example of Electrode Pattern)

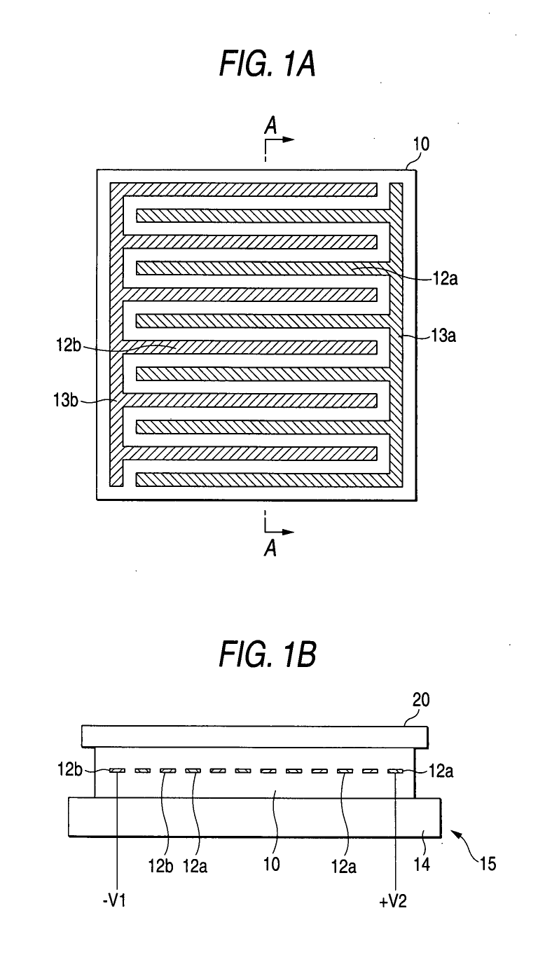

FIGS. 1 to 3 illustrate examples of electrodes 12a and 12b formed in a chuck body 10 of an electrostatic chuck. All of the electrodes 12a and 12b are formed in a pectinate shape. The positive electrode 12a and the negative electrode 12b are formed in a parallel pattern, and alternately arranged in a direction crossing the electrode pattern (A-A line direction in the figures). The positive electrode 12a are connected to a positive high-voltage power supply through a common connection pattern 13a, and the negative electrode 12b are connected to a negative high-voltage power supply through a common connection pattern 13b.

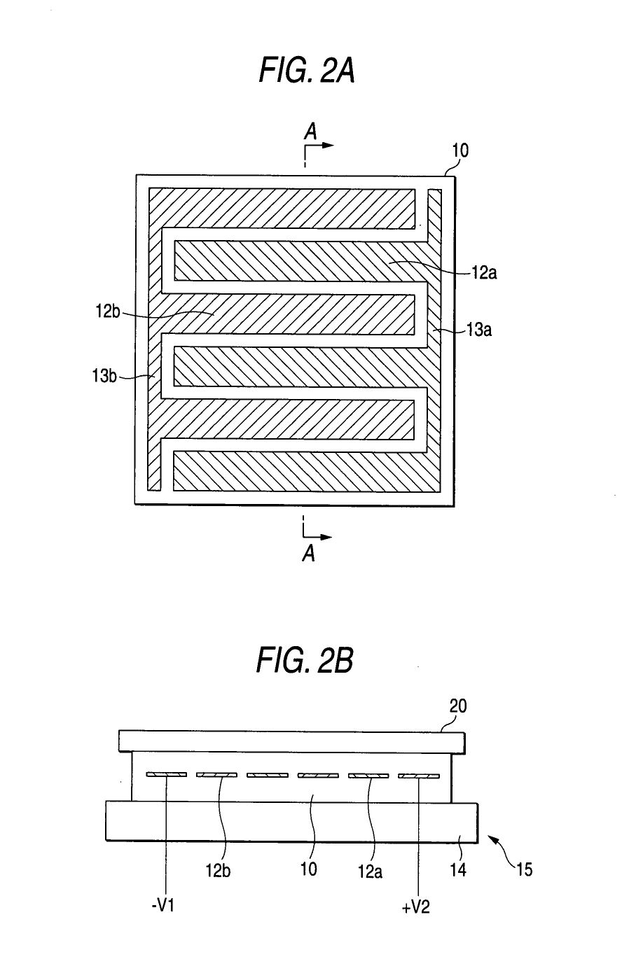

FIGS. 1B and 2B illustrate that the electrodes 12a and 12b are formed in the inner layer of the chuck body 10 formed of a ceramic substrate (dielectric layer) and are each connected to the positive power supply (+V2 volts) and the negative power supply (−V1 volt), and the chuck body 10 is supported by a base plate 14 made of a metal.

An electrostatic chuck 15 includes the chuck body 10 and the base plate 14.

The chuck body 10 is formed in a shape matched with the planar shape and the size of a work to be chucked. The chuck body 10 with a square chucking surface is illustrated as an example where a work with a square planar shape is chucked, in FIGS. 1 to 3.

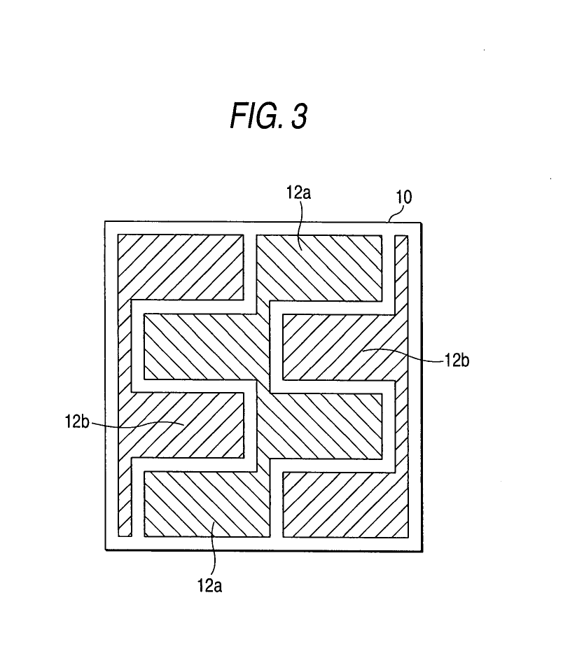

Among the electrode patterns illustrated in FIGS. 1 to 3, the electrode pattern illustrated in FIG. 1 is formed in the narrowest width, and the electrode pattern illustrated in FIG. 3 is formed in the widest width. The electrode pattern illustrated in FIG. 3 shows an example where the positive electrode 12a and the negative electrode 12b are alternately disposed in vertical and horizontal directions.

In the invention, the area ratio of the electrodes 12a and 12b formed in the chuck body 10 to the chucking surface of the chuck body 10 is an important parameter for defining characteristics of the electrostatic chuck. FIG. 1 illustrates that the area ratio of the electrodes 12a and 12b to the chucking surface of the chuck body 10 is 50% (ratio of pattern width and inter-electrode interval is 1:1), FIG. 2 illustrates that the area ratio of the electrodes 12a and 12b is 75% (ratio of pattern width and inter-electrode interval is 3:1), and FIG. 3 illustrates that the area ratio of the electrodes 12a and 12b is 83% (ratio of pattern width and inter-electrode interval is 5:1).

As described above, the power that chucks a work such as a glass substrate by a gradient force is produced by generating a non-uniform electric field on the surface of the electrostatic chuck. Accordingly, it is desirable to form a fine and high-density electrode pattern as much as possible in order to improve the operation resulting from the gradient force. That is, when the electrode pattern shown in FIG. 1 is used among the examples shown in FIGS. 1 to 3, the operation resulting from the gradient force is most generated.

On the other hand, the larger the area of the electrode pattern is, in other words, the larger the area of the electrodes occupying the chucking surface of the electrostatic chuck is, the greater a Coulomb force is. When the electrode pattern shown in FIG. 3 is used among the electrode patterns shown in FIGS. 1 to 3, the operation resulting from the Coulomb force is most generated.

(Area Ratio of Electrodes and Chucking force per Unit Area)

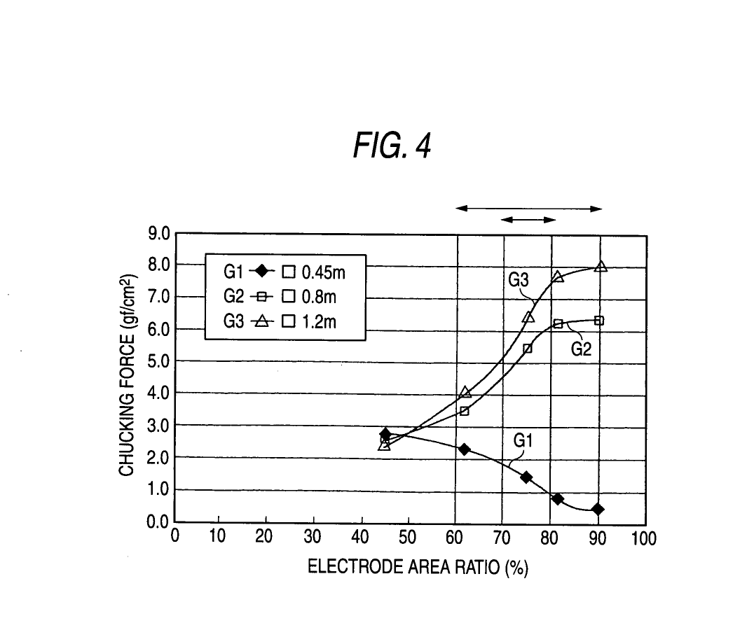

FIG. 4 is a graph illustrating a result acquired by measuring variations of a chucking force acting on a glass substrate in accordance with the area ratio of the electrodes formed in the electrostatic chuck to the chucking surface. In FIG. 4, as the glass substrates which are chucked and supported by the electrostatic chuck, a square substrate (G1) with a side of 0.45 m, a square substrate (G2) with a side of 0.8 m, and a square substrate (G3) with a side of 1.2 m are used. The measurement result in FIG. 4 shows a chucking force per unit area of the work in a case where a voltage of 4000 volts is applied between the positive electrode and the negative electrode.

The graph shown in FIG. 4 shows that the chucking forces per unit area for the glass substrates G1, G2, and G3 are not greatly different from one another when the area ratio of the electrodes is about 50%. That is, the chucking force does not depend on the size of the glass substrate when the pattern in which the electrodes 12a and 12b occupy about 50% of the chucking surface is formed as shown in FIG. 1. The gradient force acting on the glass substrate is defined by a certain chucking force per unit area. Accordingly, it is considered that when the area ratio of the electrodes is 50%, the gradient force dominantly acts on the glass substrate, and the chucking force does not depend on the size of the glass substrate.

When the area ratio of the electrodes is in the range of about 60% to 80%, the chucking force greatly varies depending on the size of the glass substrate.

That is, the chucking force per unit area for the small-sized glass substrate G1 is more greatly reduced in a case where the area ratio of the electrodes is greater than about 60%, as compared with the case where the area ratio is 50%. The pattern width of the electrodes is wider than the inter-electrode interval when the area ratio of the electrodes is greater than 60% as shown in FIG. 2. Accordingly, it is considered that the pattern generating the gradient force generated by forming fine-width electrodes in the high density can not be acquired and the gradient force is therefore reduced.

When the area ratios of the electrodes for the middle-sized glass substrate G2 and the large-sized glass substrate G3 are in the range of 60% to 80%, the chucking force per unit area rapidly increases, and the chucking force increases as the area ratio increases. Considering the above result in addition to the reduction in the chucking force in the range for the small-sized glass substrate G1, it is considered that the Coulomb force is dominant on the glass substrates G2 and G3 in the region with the electrode area ratio because of the increasing chucking force resulting from the Coulomb force with the electrode pattern formed in a wide width.

When the area ratio of the electrodes is greater than 80%, the chucking force per unit area for the glass substrate G1 is further reduced, but the chucking forces for the glass substrates G2 and G3 gradually increase. Since the electrodes occupy a large area of the glass substrate, the Coulomb force is dominant on the glass substrate G1. However, since the area itself of the glass substrate is smaller than those of the glass substrates G2 and G3, the absolute area of the electrodes is small, and thus it is considered that a sufficient chucking force can not be obtained.

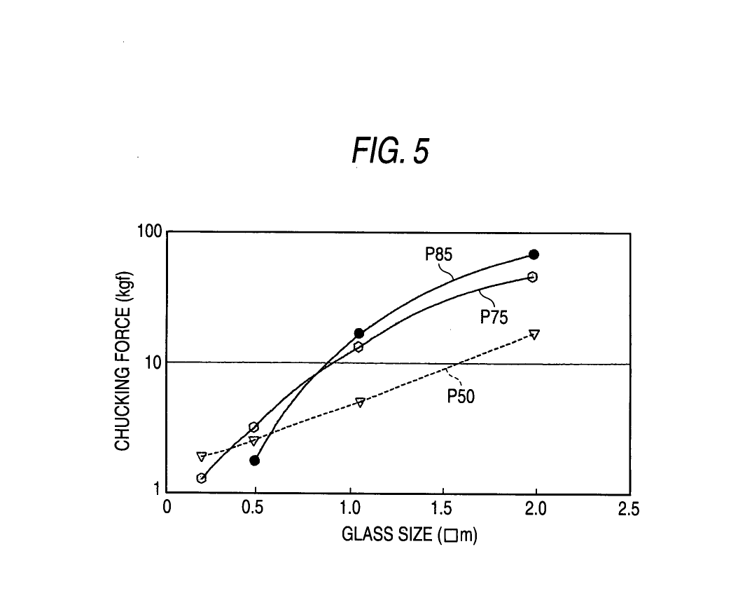

FIG. 5 is a graph illustrating a result acquired by measuring variations of the chucking force in accordance with the size of the glass substrate in cases where the area ratios of the electrodes to the chucking surface are 50% (P50), 75% (P75), and 85% (P85). The horizontal axis of the graph represents a length of the side of the glass substrate and the vertical axis of the graph represents the chucking force acting on the entire glass substrate.

In FIG. 5, when the area ratio of the electrodes formed in the electrostatic chuck is 50% (P50), the chucking force gradually increases as the size of the glass substrate increases. The result shows that the chucking force for the glass substrate increases as the area of the glass substrate increases. That is, the chucking force per unit area is uniform.

When the side of the glass substrate is about 0.5 m, the chucking forces for the cases where the area ratio of the electrode is 75% (P75) and 85% (P85) are almost the same as that for the case where the area ratio is 50% (P50). However, when the side of the glass substrate is 0.8 m (area of 0.6 m²) or greater, differences in the chucking force can be obviously revealed.

The results in FIGS. 4 and 5 shows that the chucking force acting on the square glass substrate with a side of about 0.8 m or more can effectively increase by setting the area ratio of the electrodes formed in the chuck body 10 of the electrostatic chuck 15 to the ratio in the range of 60% to 90%, and shows that the chucking force greatly increases when the area ratio of the electrode is in the range of 70% to 80%. That is, it can be seen that it is effective to form an electrode pattern so as to chuck a large-sized work by the use of the chucking force resulting from the Coulomb force.

When the chucking force acting on the glass substrate can be increased, a voltage applied to the electrodes can be reduced. Accordingly, when a work in which a circuit is formed on a substrate, such as a LCD panel, is chucked and supported to be delivered, it is possible to effectively prevent the work from being damaged due to a high voltage.

In the above-described embodiment, the electrostatic chuck chucking and supporting the square glass substrate is described based on the measurement results, but the chucking force resulting from the Coulomb force does not depend on the shape or the material of the work. For example, the embodiment can be applied to an electrostatic chuck chucking a circular work as well as the square work. That is, when a work to be chucked is made of an electrical insulating material such as a glass substrate, and is chucked and supported by the operation resulting from the Coulomb force or the gradient force, and when an electrostatic chuck having a chucking area of 0.6 m² or more is configured, the area ratio of the electrodes to the chucking surface is set to the ratio in the range of 60% to 90%, preferably in the range of 70% to 80%, thereby providing the electrostatic chuck having a very appropriate chucking force.

(Another Example of Forming Electrodes)

As described above, in the electrostatic chuck according to the invention, the electrodes occupy a large area of the chucking surface of the chuck body of the electrostatic chuck with the area ratio in the range of 60% to 90%. In order to increase the area ratio of the electrodes, the electrode portion may be formed in a wide width and the inter-electrode interval may be designed to be narrowed, as shown in FIG. 3. By forming each electrode region in a form of a large block in the chucking surface, it is possible to increase the area ratio of the electrodes. However, it is necessary to narrow the inter-electrode interval in a case where each electrode region is designed so as not to be extremely increased. However, when the inter-electrode interval is narrowed, an electrical short may be caused between the electrodes at the time of manufacturing an electrostatic chuck, and electrical discharge is caused between the electrodes at the time of applying a high voltage to the electrodes.

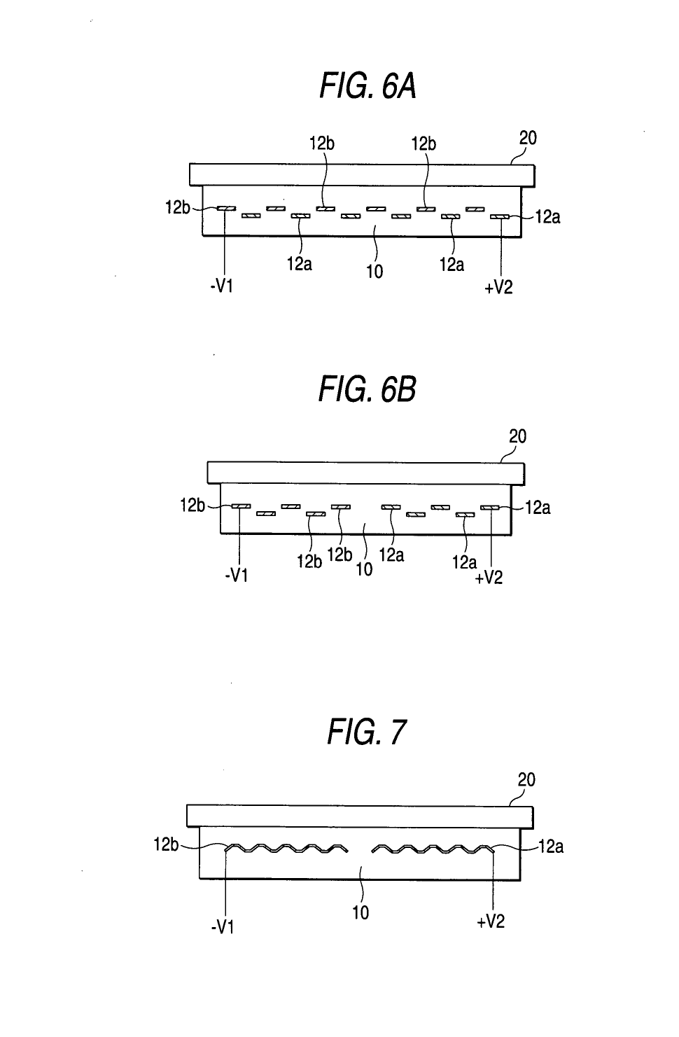

It is effective to form the electrodes 12a and 12b in plural layers in the inner layer of the chuck body 10 as shown in FIG. 6, in order that the pattern width of the electrode pattern formed in the electrostatic chuck is not to be extremely increased and the area ratio of the electrodes is increased. The base plate is omitted in the figures.

FIG. 6A is an example where the positive electrode 12a and the negative electrode 12b are formed in separate layers in the inner layer of the chuck body 10 and connected to the positive power supply and the negative power supply, respectively. FIG. 6B is an example where the positive electrode 12a and the negative electrode 12b are formed in a two-layer structure, the planar surface of the chuck body 10 is divided into two (for example, divided into two left and right parts), and the electrodes 12a and 12b are arranged in a half part and the other part.

In this manner, when the electrodes 12a and 12b are formed in the plural layers, the interlayer distance of the electrodes can be assured, thereby preventing the electrical discharge between the electrodes. In addition, since the electrodes are arranged close to each other as viewed in a planar direction, the area ratio of the electrodes can be substantially increased. In the example in FIG. 6B, in the region in which the positive electrode 12a and the negative electrode 12b are formed, the electrodes may be arranged so as to overlap the planar arrangement thereof.

A ceramic green sheet of alumina or the like is laminated, a conductive paste such as a tungsten paste is printed in accordance with the electrode pattern formed in the chuck body 10, and a green sheet is laminated thereon and baked in a plate shape, thereby forming the chuck body 10. Accordingly, by laminating and baking the green sheet in which the electrode pattern is printed in an appropriate shape, it is possible to form the chuck body 10 in which the electrodes 12a and 12b are formed in the plural layers as shown in FIG. 6.

The dielectric layer constituting the chuck body 10 is set to have a proper resistance value in view of a dechuck property of the work. A material for adjusting the resistance value is appropriately added to a ceramic material which is a main material at the time of manufacturing the ceramic green sheet so that the resistance value of the dielectric layer is adjusted.

FIG. 7 illustrates a further example of the electrodes formed in the chuck body 10. As described above, it is effective to increase the area of the electrodes, in order to more effectively generate the Coulomb force when the work made of an electrical insulating material such as a glass substrate is chucked. FIG. 7 is an example where the end face shape of the electrodes 12a and 12b formed in the inner layer of the chuck body 10 is formed to be in a waveform shape. As described above, by forming the electrodes 12a and 12b to be in a bent shape, not to be flat, the surface area of the electrodes 12a and 12b can be increased in the same planar region. In this manner, it is possible to improve the chucking operation resulting from the Coulomb force.

(Method of Chucking and Supporting Charged Work)

In an apparatus for processing a large-sized glass substrate such as a LCD panel, a work may come in contact with the air at the time of delivering it at high speed, and therefore may be charged. In addition, a work may be charged by a dry etching process such as an ion etching process. In these cases, when the charged work is delivered to the electrostatic chuck, the charging of the work causes an electrostatic chucking force caused by the electrostatic chuck to be removed. Accordingly, the chucking force of the electrostatic chuck is reduced.

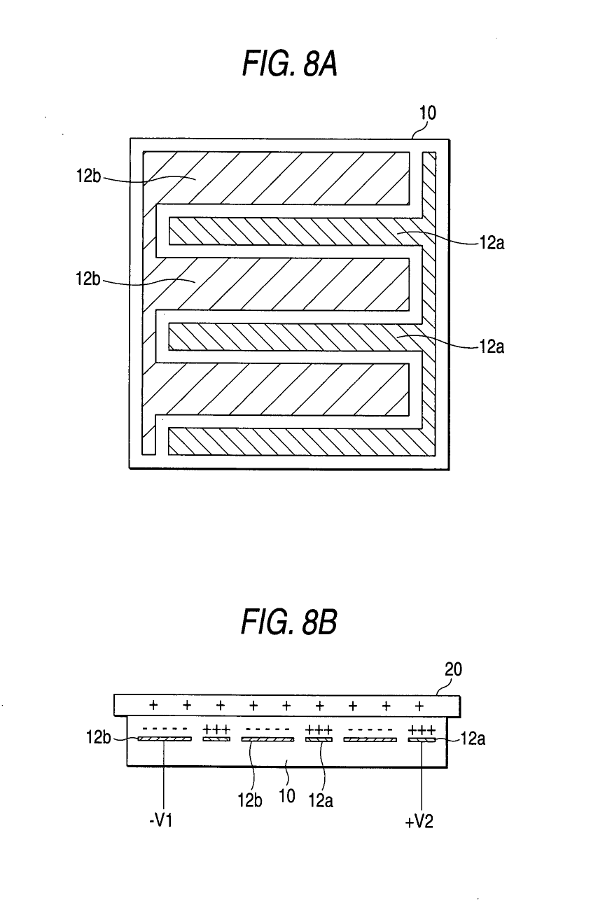

As a method of solving the problem, the pattern width of the positive electrode 12a and the negative electrode 12b formed in the electrostatic chuck can be changed as shown in FIG. 8.

When the work is positively charged, the negative electrode pattern is formed in a width wider than that of the positive electrode pattern so that the area of the negative electrode is larger than that of the positive electrode, and then the coulomb charge generated by the positive electrode 12a and the negative electrode 12b is unbalanced. The effect resulting from the charged work 20 is removed in this manner, thus a necessary chucking force can be obtained.

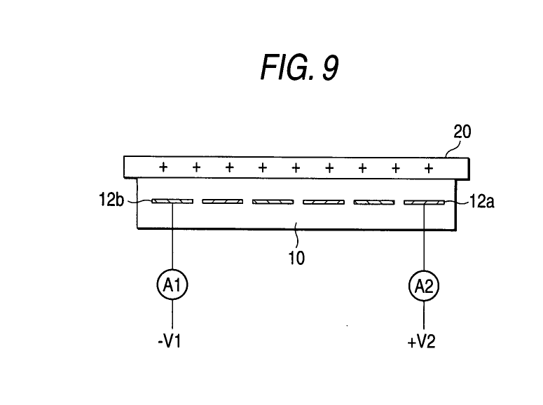

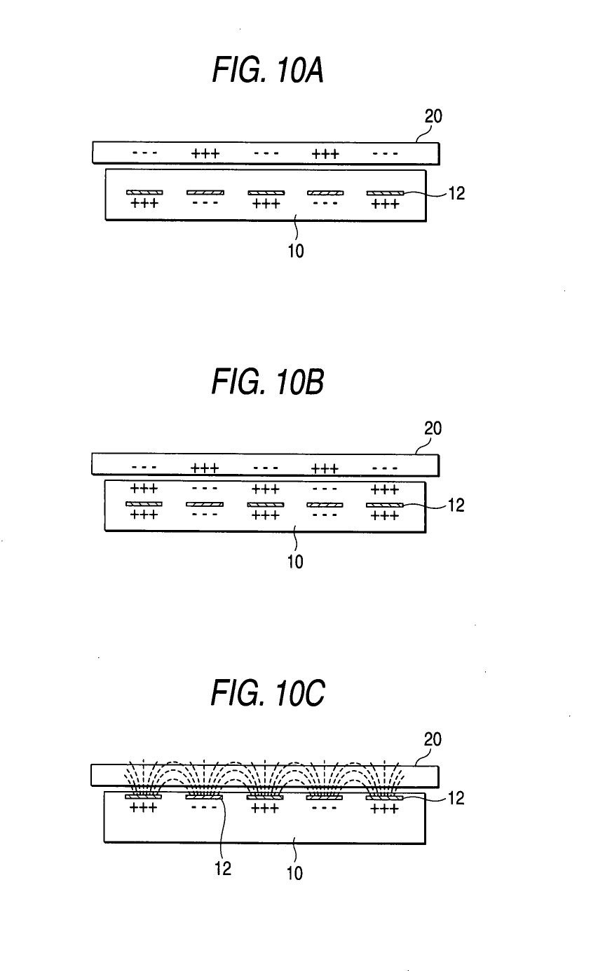

There is another method of removing the charging of the work so as to chuck and support the work by the electrostatic chuck. As shown in FIG. 9, ammeters A1 and A2 can be respectively provided for the power supply connected to the negative electrode and the power supply connected to the positive electrode to monitor the currents i1 and i2 of the ammeters A1 and A2, and supply voltages −V1 and +V2 applied to the negative electrode and the positive electrode are adjusted so that the current i1 is equal to the current i2. The charged work is stabilized in this manner, and therefore can be chucked and supported. When the charged work is delivered on the electrostatic chuck, the supply voltages −V1 and +V2 are adjusted so that the currents of the ammeters A1 and A2 are equal to each other. As a result, a charge is supplied to the electrodes so as to remove the charging of the work, thereby obtaining the original chucking force caused by the electrostatic chuck.

As described above, it is possible to reliably chuck and support even the charged work by the electrostatic chuck in accordance with the method of changing the area ratio of the electrodes with the positive and negative electrodes or the method of controlling the current values supplied to the positive and negative electrodes so as to be equal to each other (i1=12). The reason thereof is that the chucking force chucking the work results from the Coulomb force. The electrical insulating material such as a glass substrate is easy to charge, as compared with a semiconductor and the like. Accordingly, for the electrostatic chuck chucking and supporting the work made of the electrical insulating material, it is effective to remove the charging of the work to chuck and support the work. In addition, even when the pattern width of the electrode pattern is changed with the positive and negative electrodes so as to prevent the work from being charged, the area ratio of the electrodes to the chucking surface is also in the range of 60% to 90%, preferably in the range of 70% to 80% as described above.

The electrostatic chuck 15 of the above-described embodiment is formed by attaching the chuck body 10 made of the ceramic substrate as the dielectric layer to the base plate 14. An electrostatic chuck in which, in order to apply a cushioning property to the chuck body 10, a silicon rubber is attached to the base pate 14 and an electrode film in which an electrode including a copper pattern is formed and a dielectric layer including an insulating film such as a polyester film are attached to the surface of the silicon rubber so as to be laminated also may be used. The electrostatic chuck which includes the chuck body allowed to have the cushioning property is effective to chuck and support a large-sized work such as a LCD panel. The invention can be also applied to such electrostatic chuck which includes the chuck body having the cushioning property.

What is claimed is:

1. An electrostatic chuck for chucking and supporting a work made of an electrical insulating material,
the electrostatic chuck comprising:
a chuck body, and
positive and negative electrodes which are formed in the chuck body, and positive and negative voltages are applied to, wherein
an area ratio of the positive and negative electrodes to a chucking surface of the chuck body is in the range of 60% to 90%.

2. The electrostatic chuck according to claim 1, wherein
the area ratio of the electrodes to the chucking surface of the chuck body is in the range of 70% to 80%.

3. The electrostatic chuck according to claim 1, wherein
the area of the chucking surface of the chuck body is 0.6 m² or more.

4. The electrostatic chuck according to claim 1, wherein
the chuck body is formed of a dielectric material having a volume resistivity of 10¹³ Ω·cm or more.

5. The electrostatic chuck according to claim 1, wherein
the positive and negative electrodes are formed in a parallel pattern and disposed in a pectinate shape.

6. The electrostatic chuck according to claim 1, wherein
the positive and negative electrodes are provided in layers separated from each other in a thickness direction of the chuck body.
